(19) United States
(12) Patent Application Publication
(10) Pub. No.: US 2006/0249852 A1
(43) Pub. Date: Nov. 9, 2006

(54) Flip-chip semiconductor device

(75) Inventors: Shih-Kuang Chiu, Taichung (TW); Mei-Yi Sung, Taichung (TW); Chien-Ping Huang, Taichung (TW); Cheng-Hsu Hsiao, Taichung (TW)

Correspondence Address: EDWARDS & ANGELL, LLP, P.O. BOX 55874, BOSTON, MA, 02205, US

(73) Assignee: Siliconware Precision Industries Co., Ltd.

(21) Appl. No.: 11/417,548

(22) Filed: May 3, 2006

(30) Foreign Application Priority Data
May 3, 2005 (TW) 094114197

(51) Int. Cl. H01L 23/48

(52) U.S. Cl. 257/778

(57) ABSTRACT

A flip-chip semiconductor device is proposed, including a substrate, a plurality of stiffeners disposed at peripheral areas of the substrate, with a gap formed between each of the adjacent stiffeners; at least a semiconductor chip mounted on an area of the substrate surrounded by the stiffeners via flip-chip technique; and a beat sink attached to the semiconductor chip. By such arrangement, warpage of the semiconductor device may be prevented. As an opening is formed at an appropriate position of the stiffener structure, distortion of the stiffener may be avoided. Further, as the beat sink is not attached to the stiffener, solder bumps may be free from thermal stress due to mismatch in coefficient of thermal expansion between the heat sink and the substrate while preventing delamination of the heat sink caused by thermal stress.

### FIELD OF THE INVENTION

The present invention relates to flip-chip semiconductor devices, and more particularly, to a flip-chip semiconductor package having a beat sink.

### BACKGROUND OF THE INVENTION

Ball Grid Array (BGA) is an advanced semiconductor packaging technique, which is characterized in the use of a package substrate, having a front side thereof mounted with a semiconductor chip and a back side thereof mounted with a grid array of solder balls via self-alignment techniques. This thereby allows more input/output connections (I/O connections) to be provided on the same unit area of a semiconductor chip carrier to meet requirements of high integration of the semiconductor chip, such that an entire package unit can be electrically connected to an external device by the means of the solder ball.

Further, a flip-chip semiconductor package is a packaging structure in which electrical connection is provided by flip-chip technique. In such semiconductor package, an active surface of at least a chip is electrically connected to a surface of a substrate by the means of a plurality of solder bumps, wherein a plurality of solder balls served as input/output (I/O) connections are mounted on the other surface of the substrate. Such design can dramatically reduce the overall volume of the package and minimize the size ratio of the chip to the substrate. Moreover, the prior-art design of wires can be eliminated to reduce resistances and improve electrical performances, such that signal distortion during transmission can be avoided. As a result, the flip-chip semiconductor package has made its way into the mainstream of packaging technology for packaging chips and electronic elements.

However, during the operation of the highly integrated, a large amount of heat is generated but cannot be effectively dissipated, because the chip is encapsulated by an encapsulant, which is made of a resin material with a low coefficient of thermal conductivity of 0.8 w/m-k. Therefore, the performance and lifetime of the semiconductor device are adversely influenced and deteriorated.

Accordingly, a semiconductor package integrated with a heat dissipation structure is thus invented to improve heat dissipation efficiency of the semiconductor package.

For instance, the U.S. Pat. Nos. 5,724,230 and 5,587,882 have disclosed a flip-chip semiconductor device having a beat sink. Referring to FIG. 1, a cross-sectional view of a flip-chip semiconductor device having a heat sink according to the U.S. Pat. No. 5,724,230, shows that a flip-chip 11 is attached to a substrate 10, before attaching a heat sink 12 formed as a whole to the substrate 10 via a supportive portion 120 extended from a flat portion 121 of the heat sink 12, wherein a non-active surface of the flip-chip 11 is attached underneath the flat portion 121 of the heat sink to dissipate the heat generated by the flip-chip 11.

Referring to the foregoing package structure, due to differences in the coefficient of thermal expansion (CTE) between the heat sink and the substrate, and between the heat sink and the chip, thermal stress may occur, resulting in warpage of the substrate and the overall package structure. Thus, flatness of the substrate cannot be provided for mounting a plurality of solder balls. Furthermore, the heat sink may be detached because delamination may occur at the top of the substrate where the heat sink is attached. Additionally, due to stress generated by the overall package structure, solder bumps mounted on the active surface of the flip-chip to electrically connect the chip to the substrate, may bear too much stress and be cracked. In order to solve the foregoing problems, the U.S. Pat. Nos. 5,909,056 and 6,472,762 have disclosed a flip-chip semiconductor device having a heat sink. Referring to FIG. 2, a cross-sectional view of a flip-chip semiconductor device having a heat sink according to the U.S. Pat. No. 6,472,762, shows that a closed ring-shaped stiffener 23 is disposed on a substrate 20 first, such that a flip-chip 21 is attached to an area of substrate 20 surrounded by the closed ring-shaped stiffener 23. Then, a beat sink 22 is attached to the stiffener 23 and a non-active surface of the flip-chip 21 is located underneath the beat sink 22, so that the heat generated during the operation of the flip-chip 21 can be dissipated.

In the foregoing semiconductor device, the warpage problem can be prevented using the stiffener, such that the flip-chip can be successfully attached to the substrate. However, after the beat sink is attached to the stiffener, mismatches of the coefficient of thermal expansion (CTE) still exist between various elements that are used to assemble the package structure. More particularly, when the beat sink is attached to the stiffener and the chip, cracks of the solder bumps may occur because the solder bumps of the flip-chip are affected by thermal stress generated by the heat sink and the substrate. Furthermore, the stiffener is a closed ring-shaped stiffener structure. Thus, after the stiffener is covered by the heat sink to enclose the chip, the air existed between the heat sink and the stiffener may be easily heated and expanded during a subsequent process requiring surface mount technology (SMT), resulting in the delamination of the heat sink. Additionally, when the closed ring-shaped stiffener is used to solve the warpage problem of the substrate, the stress formed in the corner of the stiffener still cannot be released, thereby causing distortion of the stiffener. Moreover, a warpage problem may also occur in the diagonal direction of the substrate, such that the flatness of the substrate for mounting the solder ball may be adversely influenced.

FIG. 3 is a cross-sectional view of a flip-chip semiconductor device having a heat sink according to the U.S. Pat. No. 6,413,353. Referring to FIG. 3, a heat sink 32 is directly attached to a flip-chip 31 without being attached to a substrate 30. Therefore, cracks of solder bumps 34 caused by thermal stress due to mismatches in coefficient of thermal expansion between the heat sink 32 and the substrate 30 can be prevented. The solder bump 34 serves to electrically connect the flip-chip 31 to the substrate 30.

Yet, the warpage problem of the substrate still cannot be effectively prevented in the foregoing semiconductor device. The warpage problem can get worse with a semiconductor device comprising a large-size chip. That is because once a slight warpage occurs, the solder bump located at peripheral areas of the flip-chip may not be able to be attached to the substrate, resulting in loss of electrical connection, as a consequence.

Therefore, the problem to be solved herein is to provide a flip-chip semiconductor device that is able to prevent problems such as warpage, distortion of stiffeners, delamination of a heat sink and cracks of solder bumps, while ensuring flatness of the substrate for mounting a plurality of solder balls firmly.

### SUMMARY OF THE INVENTION

In light of the above prior-art drawbacks, a primary objective of the present invention is to provide a flip-chip semiconductor device, which can prevent warpage.

Another objective of the present invention is to provide a flip-chip semiconductor device, which can prevent distortion of stiffeners.

Still another objective of the present invention is to provide a flip-chip semiconductor device, which can prevent delamination of a beat sink.

A further objective of the present invention is to provide a flip-chip semiconductor device, which prevent cracks of solder bumps.

A further objective of the present invention is to provide a flip-chip semiconductor device, which can maintain flatness of a substrate for effectively mounting a plurality of solder balls.

In accordance with the foregoing and other objectives, the present invention proposes a flip-chip semiconductor device, comprising a substrate; a plurality of stiffeners disposed at peripheral areas of the substrate, wherein a gap is formed between each of the adjacent stiffeners; at least a semiconductor chip mounted on an area of the substrate surrounded by the stiffener via a flip-chip technique; and a heat sink attached to the semiconductor chip.

Accordingly, the flip-chip semiconductor device of the present invention comprises the substrate with peripheral areas thereof surrounded by a plurality of stiffeners, having gaps formed between each of the adjacent stiffeners, such that a ring-shaped stiffener structure having an opening is formed. The ring-shaped stiffener structure may effectively prevent warpage of the semiconductor device and ensure surface flatness of the substrate, so as to solve problems of having solder bumps located at peripheral areas of a large-size flip chip but being unable to be mounted to a substrate in the prior art. Further, as the stiffener structure has a plurality of stiffeners disposed at the peripheral areas of the substrate, the opening formed at an appropriate position of the stiffener structure may prevent distortion of the stiffener from occurring, such that warpage occurred along the diagonal of the substrate way be avoided as well.

Moreover, as the flip-chip semiconductor device of the present invention has the heat sink directly attached to the chip without being attached to the stiffeners, the solder bump may be free from thermal stress due to mismatch in coefficient of thermal expansion between the beat sink and the substrate, such that effect of thermal stress on delamination of the heat sink may be avoided.

Additionally, as the flip-chip semiconductor device of the present invention has the unclosed ring-shaped stiffener structure and the heat sink attached to the chip without being attached to the stiffener, air existed between the ring-shaped stiffener structure and the heat sink would not be trapped, allowing heated air to escape, thereby preventing thermal expansion.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 (PRIOR ART) is a cross-sectional view of a flip-chip semiconductor device configured with a beat sink according to the U.S. Pat. No. 5,724,230;

FIG. 2 (PRIOR ART) is a cross-sectional view of a flip-chip semiconductor device configured with a heat sink according to the U.S. Pat. No. 6,472,762;

FIG. 3 (PRIOR ART) is a cross-sectional view of a flip-chip semiconductor device configured with a beat sink according to the U.S. Pat. No. 6,413,353;

FIG. 4A is a cross-sectional view of a flip-chip semiconductor device according to the present invention;

FIG. 4B is a planar view of a flip-chip semiconductor device according to the present invention; and

FIG. 5A and FIG. 5B are planar views of a flip-chip semiconductor device according to different embodiments of the present invention.

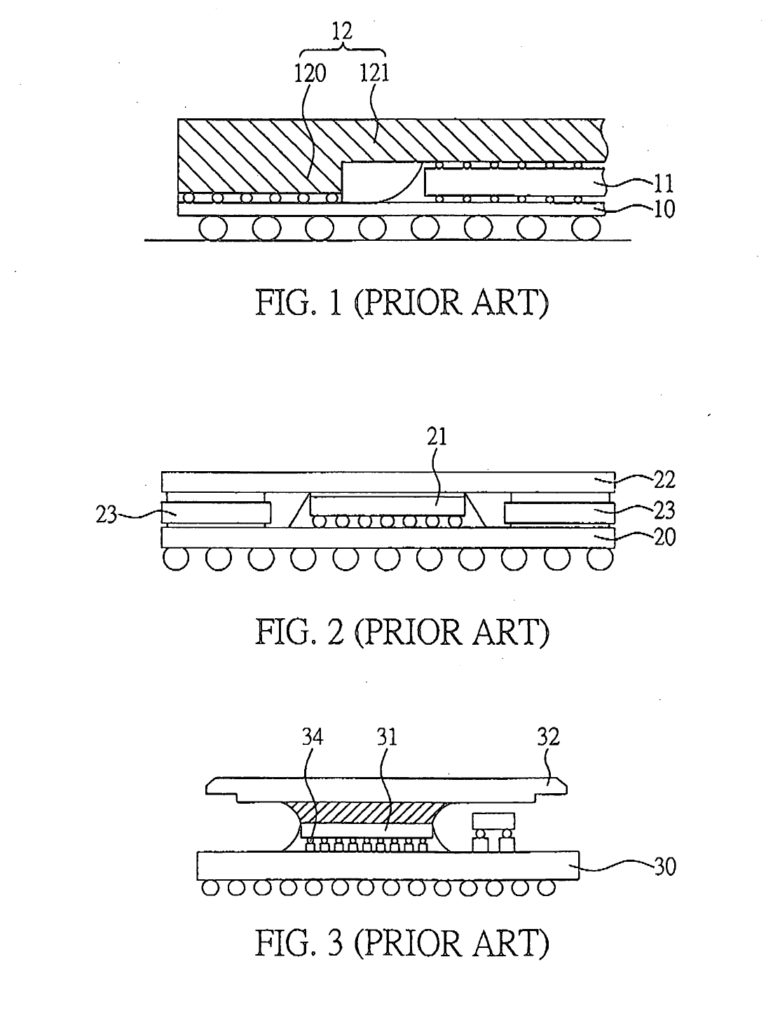

### DETAILED DESCRIPTION OF THE EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

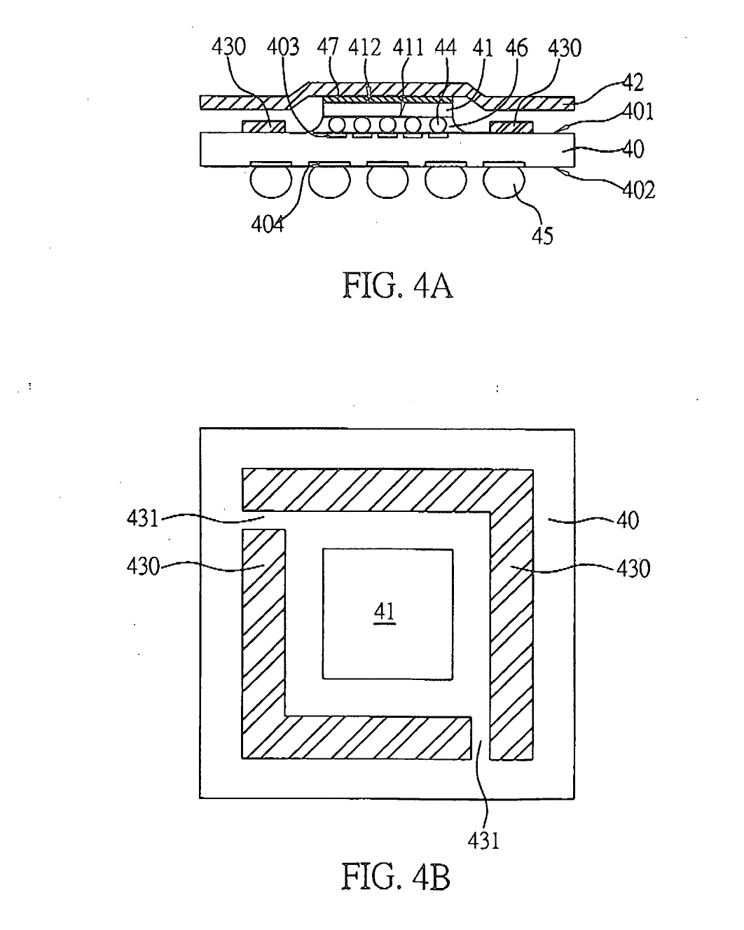

FIG. 4A is a cross-sectional view of a flip-chip semiconductor device according to the present invention, and FIG. 4B is a planar view of a flip-chip semiconductor device according to the present invention. The flip-chip semiconductor device comprises a substrate 40; a plurality of stiffeners 430 disposed at surrounding peripheral areas of the substrate 40, wherein a gap 431 is formed between each of the adjacent stiffeners 430; at least a semiconductor chip 41 mounted on an area of the substrate 40 surrounded by the stiffener 430, by flip-chip bonding technique; and a heat sink 42 attached to the semiconductor chip 41.

The substrate 40 may be a ball grid array (BGA) substrate having a first surface 401 and a corresponding second surface 402, wherein a plurality of bond pads 403 and 404 may be respectively formed on the first surface 401 and the second surface 402. Further, the bond pads 403 of the first surface 401 allow the semiconductor chip 41 to be electrically connected to the substrate 40 via solder bumps 44 by flip-chip technique; and the bond pads 404 of the second surface 402 allow a plurality of solder balls 45 to be mounted thereon, such that the semiconductor device can be electrically connected to an external device such as a printed circuit board (PCB).

Each stiffener 430 is made of a material that has a coefficient of thermal expansion (CTE) similar to the CTE of the substrate 40, such as copper metal or polymer resin. The stiffeners 430 are disposed at the peripheral areas of the substrate 40 to form a ring-shaped stiffener structure with an opening, wherein a gap 431 is formed between each of the adjacent stiffeners 430, such that warpage of the substrate 40 may be prevented by the ring-shaped stiffener structure and flatness of the substrate 40 may be ensured so as to improve reliability of subsequent fabrication processes. Further, as the flip-chip semiconductor device of the present invention comprises the stiffener structure having a plurality of stiffeners 430 disposed at the peripheral areas of the substrate 40, and the gap 431 formed between each of the adjacent stiffeners 430, distortion of stiffeners caused by stress concentration effect may be avoided and occurrence of warpage at a diagonal direction of the substrate 40 may also be prevented.

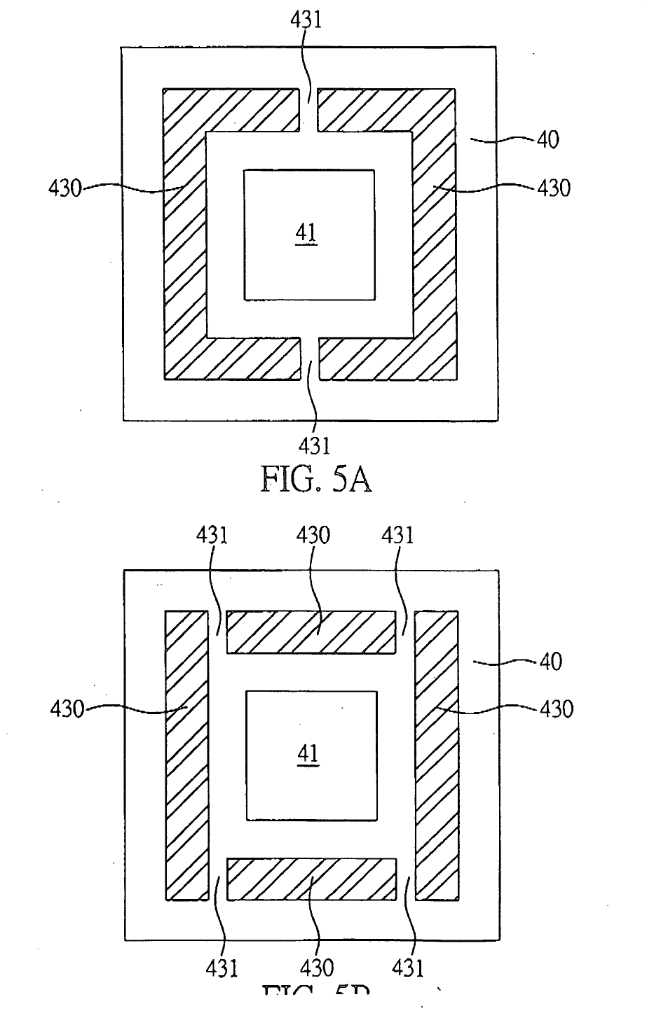

Furthermore, in addition to an exemplary arrangement of the stiffeners 430, being disposed on the peripheral areas of the substrate 40, as shown in FIG. 4B, the stiffeners 430 may also be disposed on the substrate 40 with the gaps 431 formed therebetween, as shown in FIG. 5A and FIG. 5B.

The flip-chip semiconductor chip 41 is provided with an active surface 411 and a corresponding non-active surface 412, wherein the solder bumps 44 formed on the active surface 411 of the chip 41 are mounted and electrically connected to the bond pads 403 of the first surface 401 of the substrate 40. Further, the chip 41 is located on the area of the substrate 40 surrounded by the stiffeners 430. Furthermore, underfill 46 may be filled into a gap formed between the chip 41 and substrate 40, such that mismatch in coefficient of thermal expansion between the chip 41 and the substrate 40 may be eliminated and stress exerted on the solder bump 44 may be reduced.

The heat sink 42 may be attached to the non-active surface 412 of the chip 41 via a thermal conductive adhesive layer 47, such that the beat generated during operation of the chip 41 may be effectively dissipated by the heat sink 42. The shape of the heat sink 42 may be a structure formed with a curved portion as shown in FIG. 4A, or alternatively, a flat structure or a structure formed in any other shapes, as long as the heat sink 42 is prevented from being attached to the stiffeners 430.

Accordingly, the flip-chip semiconductor device proposed in the present invention comprises a plurality of stiffeners disposed at the surrounding peripheral areas of the substrate, with the gaps formed between the stiffeners, such that the ring-shaped stiffener structure having an opening is formed to effectively prevent warpage of the semiconductor device, so as to ensure surface flatness of the substrate to solve problems of the prior art related to having solder bumps located at peripheral areas of a large-size flip chip but being unable to be mounted to a substrate. Further, as the stiffener structure has a plurality of stiffeners disposed at the peripheral areas of the substrate, the opening formed at an appropriate position of the stiffener structure may prevent distortion of the stiffener from occurring, such that warpage occurred along the diagonal of the substrate may be avoided as well.

Moreover, as the flip-chip semiconductor device of the present invention has the heat sink directly attached to the chip without being attached to the stiffeners, the solder bump may be free from thermal stress due to mismatch in coefficient of thermal expansion between the heat sink and the substrate, such that effect of thermal stress on delamination of the heat sink may be avoided.

Additionally, as the flip-chip semiconductor device of the present invention has the unclosed ring-shaped stiffener structure and the heat sink attached to the chip without being attached to the stiffener, air existed between the ring-shaped stiffener structure and the heat sink would not be trapped and heated, thereby preventing thermal expansion.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A flip-chip semiconductor device, comprising:
a substrate;
a plurality of stiffeners disposed at surrounding peripheral areas of the substrate, wherein a gap is formed between each of the adjacent stiffeners;
at least a semiconductor chip mounted on an area of the substrate surrounded by the stiffeners via flip-chip technique; and
a heat sink attached to the semiconductor chip.

2. The flip-chip semiconductor device of claim 1, wherein the substrate is a ball grid array (BGA) substrate.

3. The flip-chip semiconductor device of claim 1, wherein a plurality of solder balls are mounted on a second surface of the substrate.

4. The flip-chip semiconductor device of claim 1, wherein the stiffener is made of a material having a coefficient of thermal expansion (CTE) similar to a CTE of the substrate.

5. The flip-chip semiconductor device of claim 4, wherein the stiffener is made of copper metal.

6. The flip-chip semiconductor device of claim 4, wherein the stiffener is made of polymer resin.

7. The flip-chip semiconductor device of claim 1, wherein the stiffeners are arranged with gaps formed therebetween at the peripheral areas of the substrate, such that a ring-shaped stiffener structure having an opening is formed.

8. The flip-chip semiconductor device of claim 1, wherein a gap formed between the chip and the substrate is filled with underfill.

9. The flip-chip semiconductor device of claim 1, wherein the semiconductor chip is provided with an active surface and a non-active surface.

10. The flip-chip semiconductor device of claim 9, wherein the semiconductor chip is mounted and electrically connected to the substrate by the means of solder bumps formed on the active surface of the semiconductor chip.

11. The flip-chip semiconductor device of claim 9, wherein the beat sink is attached to the non-active surface of the semiconductor chip via a thermal conductive adhesive layer.

12. The flip-chip semiconductor device of claim 1, wherein the heat sink is not directly attached to the stiffener.
